(19) United States
(12) Patent Application Publication
(10) Pub. No.: US 2010/0320580 A1
(43) Pub. Date: Dec. 23, 2010

(54) EQUIPOTENTIAL PAD CONNECTION

(75) Inventors: Tomoyuki Shibata, Tokyo (JP); Toru Chonan, Tokyo (JP); Tsuneo Abe, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/788,866

(22) Filed: May 27, 2010

(30) Foreign Application Priority Data
Jun. 1, 2009 (JP) 2009-132138
Apr. 12, 2010 (JP) 2010-091354

(51) Int. Cl. H01L 23/495; H01L 23/48

(52) U.S. Cl. 257/676; 257/738; 257/E23.021; 257/E23.031

(57) ABSTRACT

A conduction member is used to connect in-chip equipotential pads 20 that have the same potential in a semiconductor device through PKG ball 10 arranged on the semiconductor device.

### BACKGROUND OF THE INVENTION

1. Field of the Invention

The present invention relates to a semiconductor device.

2. Description of the Related Art

Generally, pads with the same potential in a semiconductor device (semiconductor chip) are connected by the same lead frame, connected by wires on split lead frames, or connected by a tape pattern to reduce the penetration of asynchronous noise, etc.

JP 2007-324291A discloses a technique of separating the pads and connecting the pads of terminals that have the same functions by wires.

However, there is a problem in the noise separation in which a sufficient effect cannot be obtained as the process speeds up and as power consumption increases in the semiconductor chips.

Therefore, a large effect can be obtained in which noise is separated by separating electrode pads that have the same potential along with solder ball terminals that are arranged in the semiconductor device. However, in that case, there is a problem in which the number of solder ball terminals increases, which leads to an increase in the PKG cost of the semiconductor device and to a reduction in the versatility.

### SUMMARY

A semiconductor device of the present invention uses a conduction member to connect electrode pads with the same potential in the semiconductor device through a solder ball terminal arranged in the semiconductor device.

As described, according to the present invention, a conduction member is used to connect electrode pads that have the same potential in a semiconductor device through a solder ball terminal arranged in the semiconductor device. Therefore, the penetration of noise can be reduced without increasing the number of solder ball terminals.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram showing an embodiment of a general semiconductor device;

FIG. 2 is a diagram showing a first embodiment of a semiconductor device of the present invention;

FIG. 3 is an enlarged view of part A surrounded by a broken line in the semiconductor device shown in FIG. 1;

FIG. 4 is an enlarged view of part B surrounded by a broken line in the semiconductor device shown in FIG. 2;

FIG. 5 is a cross-sectional view showing a schematic configuration of a BGA semiconductor device according to a second embodiment;

FIG. 6 is a diagram showing a wiring structure formed on an insulating substrate shown in FIG. 5;

FIG. 7 is a diagram showing a wiring structure of a semiconductor device according to a third embodiment; and

FIG. 8 is a cross-sectional view showing a schematic configuration of a wBGA semiconductor device.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

A first embodiment of a semiconductor device of the present invention will now be described with reference to the drawings. The first embodiment will be described in comparison with a general semiconductor device.

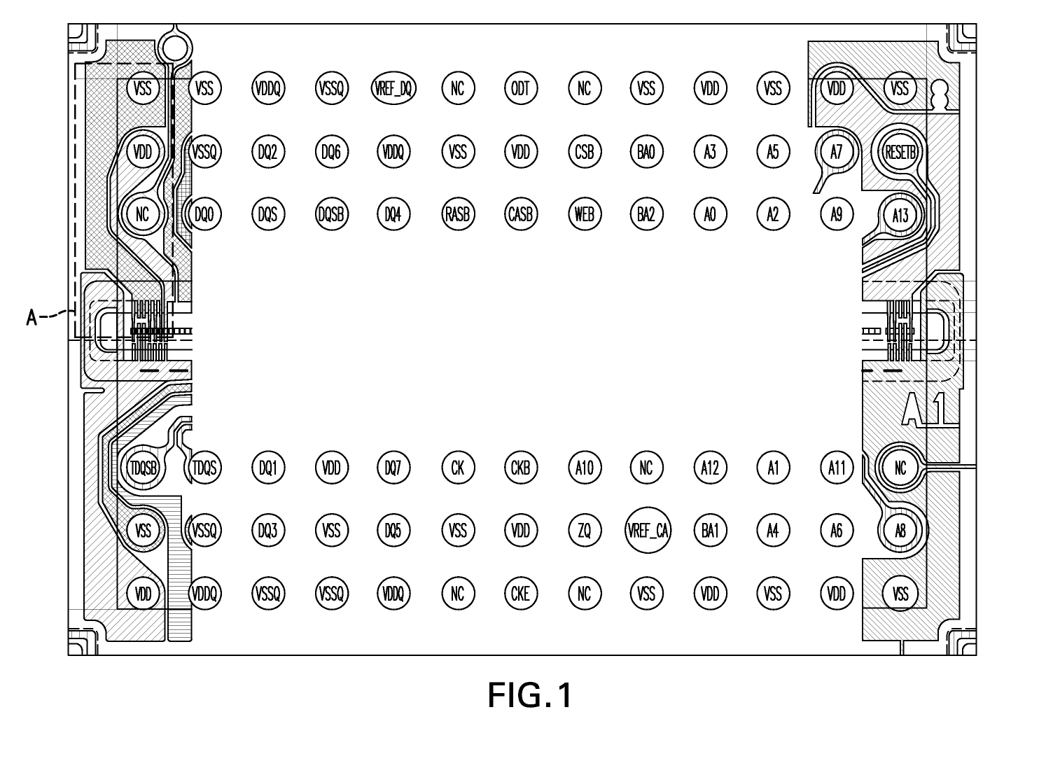

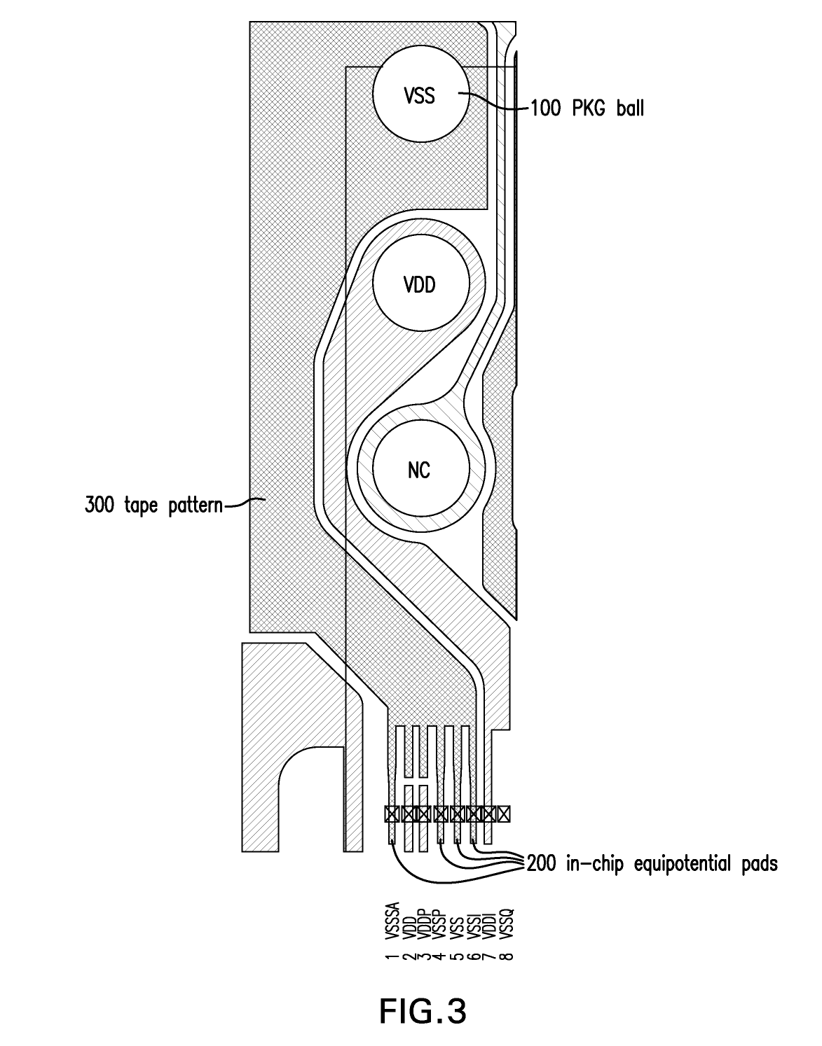

Part A in the semiconductor device shown in FIG. 1 will be described with reference to FIG. 3.

As shown in FIG. 3, PKG ball 100 as a solder ball terminal and four in-chip equipotential pads 200 with the same potential are arranged in part A surrounded by a broken line in the semiconductor device shown in FIG. 1. PKG ball 100 and in-chip equipotential pads 200 are connected using tape pattern 300 in which a connection (wiring) pattern between the terminals in the semiconductor device is formed in a tape shape.

In this case, as described, the penetration of asynchronous noise, etc. occurs between in-chip equipotential pads 200.

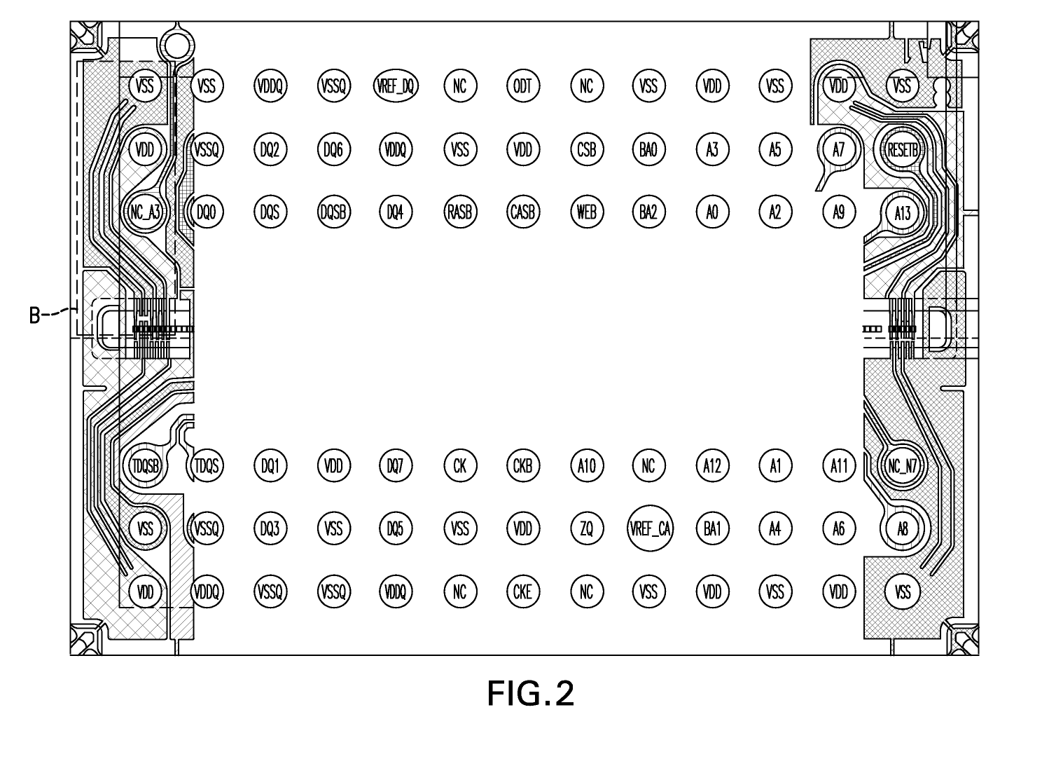

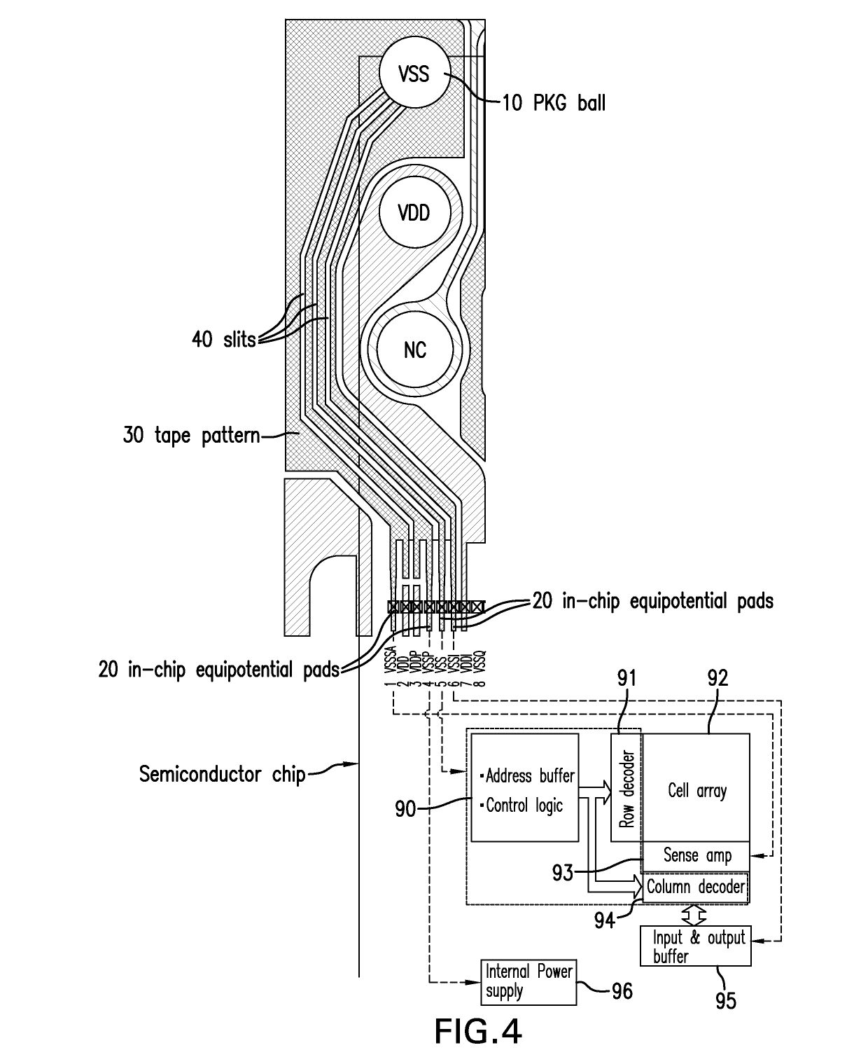

Part B of a semiconductor device shown in FIG. 2 will be described with reference to FIG. 4.

As shown in FIG. 4, PKG ball 10 as a solder ball terminal and four in-chip equipotential pads 20 that have the same potential are arranged in part B surrounded by a broken line in the semiconductor device (semiconductor chip) shown in FIG. 2. PKG ball 10 and in-chip equipotential pads 20 are connected using tape pattern 30 in which a connection (wiring) pattern between the terminals in the semiconductor device is formed in a tape shape. In tape pattern 30, slit-shaped cuts (slits 40) are provided for in-chip equipotential pads 20, which are divided for noise separation, with PKG ball 10 serving as a base point. Slits 40 are provided so as to separate in-chip equipotential pads 20 from each other. Therefore, four in-chip equipotential pads 20 are connected to each other using tape pattern 30 through PKG ball 10.

As shown in FIG. 4, address buffer and control logic 90, row decoder 91, cell array 92, sense amp 93, column decoder 94, input and output buffer 95 and internal power supply 96 are provided in the semiconductor chip. As shown in FIG. 4, one of in-chip equipotential pads 20 is connected to address buffer and control logic 90. As shown in FIG. 4, the other in-chip equipotential pads 20 is connected to sense amp 93 As shown in FIG. 4, the other in-chip equipotential pads 20 is connected to input and output buffer 95. As shown in FIG. 4, the other in-chip equipotential pads 20 is connected to internal power supply 96.

As shown in FIG. 4, slits 40 are provided from in-chip equipotential pads 20 to PKG ball 10 or close to PKG ball 10. The distance of proximity (distance between the edges of slits 40 on the PKG ball 10 side and PKG ball 10) is changed in accordance with the characteristics of the semiconductor devices.

In the semiconductor device shown in FIG. 4, slits 40 (three slits 40 in this case) are provided between four in-chip equipotential pads 20. Therefore, in-chip equipotential pads 20 are connected to each other through PKG ball 10.

In this way, in-chip equipotential pads 20 are connected to each other using tape pattern 30 including slits 40 with PKG ball 10 serving as a base point. As a result, connection points between equipotentials where the noise separation is needed are parts having the lowest impedance. Therefore, the penetration of noise can be significantly reduced without increasing the number of PKG balls 10.

In-chip equipotential pads 20 and PKG ball 10 may be connected using a conduction member other than tape pattern 30. For example, a lead frame including a plurality of leads may be used in place of tape pattern 30. In that case, slits 40 shown in FIG. 4 are provided to lead parts from in-chip equipotential pads 20, adjacent to each other, to PKG ball 10 or close to PKG ball 10.

The same effect can be obtained by applying the same connection to a part other than part B shown in FIG. 2. Therefore, although an example has been described in which PKG ball 10 in FIG. 4 is a VSS terminal ball (power terminal) shown in FIG. 2, the arrangement is not limited to this.

### Second Embodiment

A second embodiment of the semiconductor device of the present invention will now be described. The semiconductor device is a BGA (Ball Grid Array) semiconductor device in the example of the present embodiment.

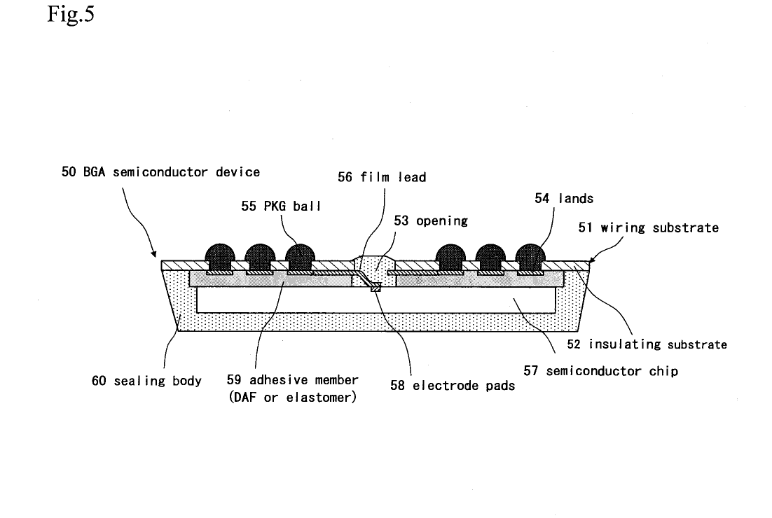

Referring to FIG. 5, BGA semiconductor device 50 includes wiring substrate 51 which is substantially rectangle and on which a predetermined wiring pattern is formed. Wiring substrate 51 is a flexible wiring substrate, and a predetermined pattern wiring made of conductive materials, such as Cu, is formed on a polyimide base material which is insulating substrate 52. Opening 53 is formed on the central area of insulating substrate 52.

Lands 54 (external terminals) are arranged in a lattice pattern at predetermined intervals on the other side of insulating substrate 52. Holes are formed at locations corresponding to lands 54 of insulating substrate 52, and PKG balls 55, which are solder ball terminals, are mounted on lands 54 exposed from the holes.

An inner lead (film lead 56) is arranged to protrude into opening 53 of insulating substrate 52, and the inner lead is electrically connected to electrode pad 58 of semiconductor chip 57 described below. The inner lead and lands 54 corresponding to the inner lead are electrically connected to each other by the pattern wiring of wiring substrate 51. In the present embodiment, the pattern wiring connected to the electrode pads for power or for GND (ground) is formed in a plane pattern (solid pattern) on insulating substrate 52.

Semiconductor chip 57 is mounted on one side opposing the other side of wiring substrate 51 through adhesive member 59, such as DAF (Die Attached Film) or elastomer. Semiconductor chip 57 is a substantially rectangle plate. For example, a memory circuit and electrode pads 58 are formed on one side, and semiconductor chip 57 is mounted with, one side facing wiring substrate 51.

Electrode pads 58 include equipotential electrode pads 58 for power, GND (ground), etc. having the same potential, and are arranged in a line at the center part of semiconductor chip 57. Semiconductor chip 57 is mounted on wiring substrate 51 so that electrode pads 58 of semiconductor chip 57 are exposed from opening 53 of wiring substrate 51. A passivation film not shown is formed on one side excluding electrode pads 58 of semiconductor chip 57 to protect the circuit forming surface.

Electrode pads 58 formed on semiconductor chip 57 are electrically connected by connecting inner leads arranged on corresponding openings 53 by inner lead bonding.

Sealing body 60 is formed on one side of wiring substrate 51 and in opening 53, and sealing body 60 covers semiconductor chip 57, electrode pads 58, and the inner leads. Sealing body 60 is made of a thermoset resin, such as an epoxy resin. Sealing body 60 protects the connection parts of semiconductor chip 57 and the inner leads from the outside.

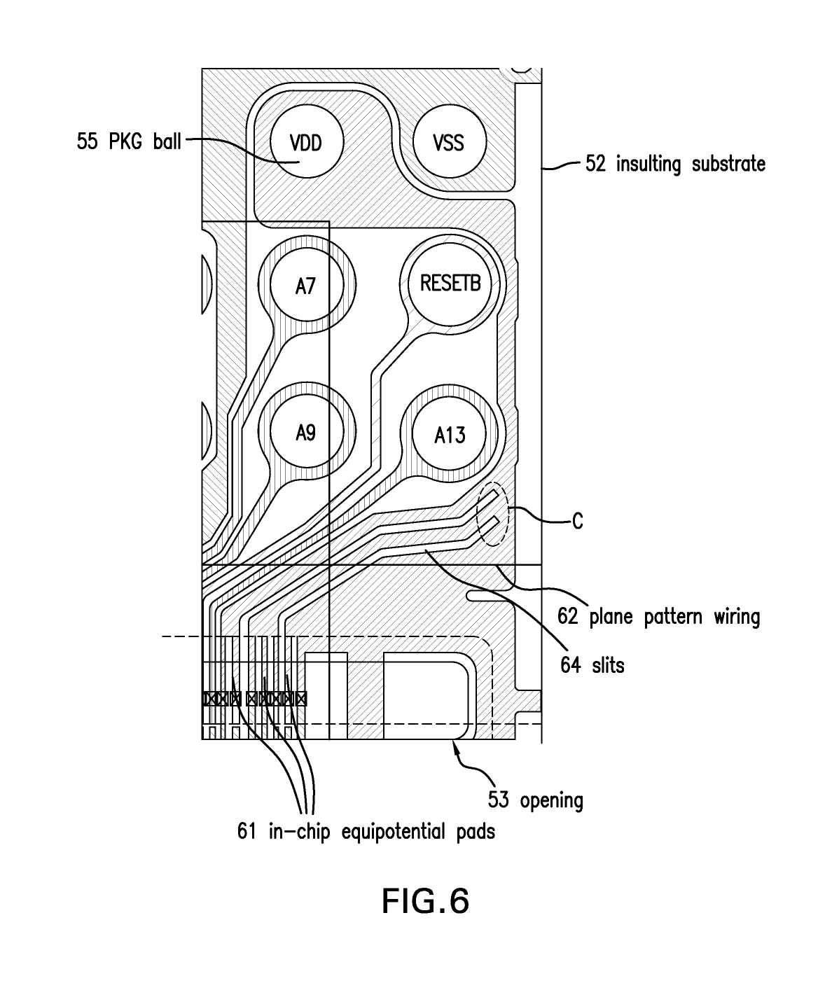

The plane pattern (solid pattern) formed on insulating substrate 52 shown in FIG. 5 will be described with reference to FIG. 6.

As shown in FIG. 6, in the present embodiment, a pattern wiring connected to a plurality of inner leads corresponding to adjacent electrode pads 58 (in-chip equipotential pads 61) having the same potential is plane pattern wiring 62 configured in a plane pattern (solid pattern) shape. In plane pattern wiring 62, slits 64 are formed toward PKG ball 55 as an external terminal from connections of the inner leads connected to the plurality of electrode pads. The width of the slits can be any width as long as pattern processing can be performed, and for example, slits are formed that have about a 30 μm width.

As shown in FIG. 6, slits 64 formed on plane pattern wiring 62 extend up to, for example, a part in the middle (C shown in FIG. 6) where the width of plane pattern wiring 62 is not more than 90 μm. For example, if the width of plane pattern wiring 62 is about 90 μm, wiring with not less than 30 μm width, which is a width that can ensure reliability in the processing of pattern wiring, can be formed even if slit 64 having a 30 μm width is provided.

In this way, slits 64 extending toward PKG ball 55 from the connection parts of the inner leads are arranged on plane pattern wiring 62 to separate connection wiring from in-chip equipotential pads 61. This can reduce the penetration of noise without increasing the number of PKG balls 55. Furthermore, slits 64 formed on plane pattern wiring 62 are extended close to the part where the width of plane pattern wiring 62 is not more than 90 μm. This can reduce the penetration of noise while ensuring the reliability of wiring. Furthermore, plane pattern wiring 62 is arranged on the edge of wiring substrate 51, and slits 64 are not formed at a part that is used for wiring the outer side of PKG ball 55 where the width is as thin as 30 to 90 μm. Therefore, the size of the wiring substrate can be smaller than the size of the wiring substrate in the first embodiment. This can miniaturize the semiconductor device.

Forming plane pattern wiring 62 on wiring substrate 51 can prevent the warpage of the semiconductor device.

### Third Embodiment

A third embodiment of the semiconductor device of the present invention will now be described.

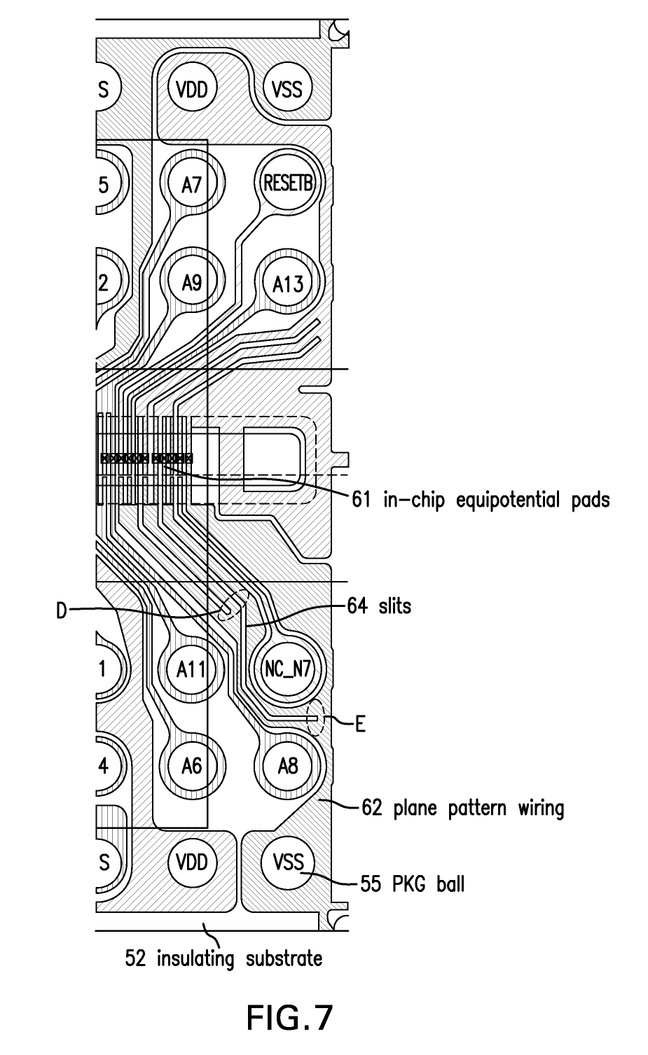

Referring to FIG. 7, slits 64 formed on plane pattern wiring 62 are configured so that, for example, two slits 64 extend up to a part in the middle (D shown in FIG. 7) where the width of plane pattern wiring 62 is not more than 150 μm, and one slit 64 extends up to a part (E shown in FIG. 7) where the width is not more than 90 μm. If the width of the plane pattern is about 150 μm, three wires with not less than 30 μm width, which is a width that can ensure reliability in the processing of pattern wiring, can be formed even if slits 64 with a 30 μm width are provided. In this way, the same effects as in the second embodiment can be obtained, and an application of the invention to three or more equipotential electrode pads (in-chip equipotential pads 61) is also possible.

Although the present invention has been described based on the first to third embodiments, the present invention is not limited to the embodiments, and it is obvious that various changes can be made without departing from the scope of the present invention. For example, although a flexible wiring substrate made of a polyimide base material is used in the description of the embodiments, the present invention may also be applied to a wiring substrate made of a glass epoxy base material.

Furthermore, although a wiring substrate with an opening formed at the central area is used in the description of the embodiments, a wiring substrate, in which an opening completely separates the area into two areas, may also be used.

Furthermore, although a one-layer substrate including a wiring layer only on the other side of the insulating substrate is used in the description of the embodiments, the present invention may also be applied to a multilayer wiring substrate such as a two-layer substrate.

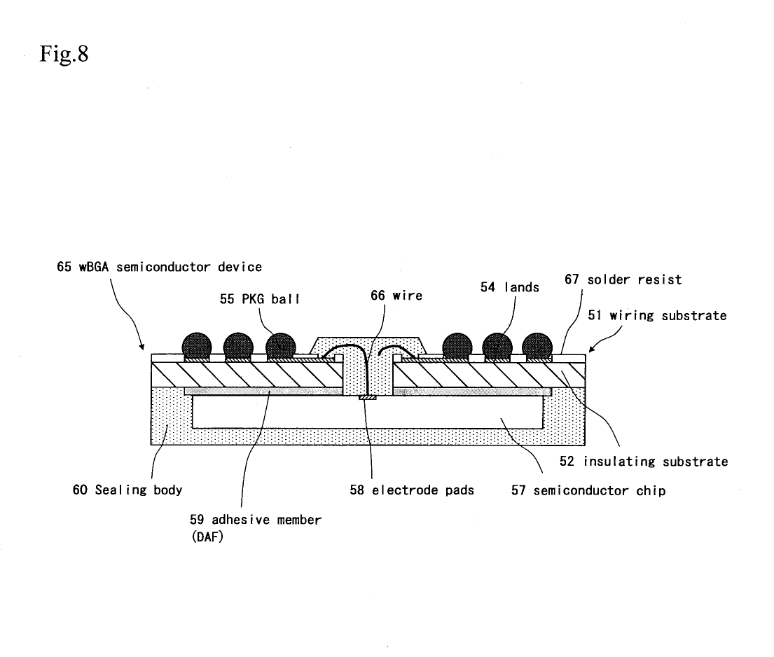

Furthermore, although the present invention is applied to a μBGA semiconductor device using a film lead in the description, the present invention may also be applied to wBGA (Window BGA) semiconductor device 65, etc., as shown in FIG. 8 as long as plane pattern wiring is formed on the wiring substrate in the semiconductor device.

As shown in FIG. 8, in wBGA semiconductor device 65, electrode pad 58 of semiconductor chip 57 and corresponding lands 54 are electrically connected using wire 66. Solder resist 67, as an ink that serves as an insulating film, covers the surface of wiring substrate 51 to protect the wiring pattern.

In the wBGA semiconductor device, the slits formed on the plane pattern wiring extend up to a part in the middle where, for example, the width of the plane pattern is not more than 120 μm. For example, if the width of the plane pattern is about 120 μm, wiring with not less than 40 μm width, which is a width that can ensure reliability in the processing of pattern wiring, can be formed even if a slit with 40 μm width is provided.

It is apparent that the present invention is not limited to the above embodiments, but may be modified and changed without departing from the scope and spirit of the invention.

1. A semiconductor device that uses a conduction member to connect electrode pads having the same potential in the semiconductor device through a solder ball terminal arranged in the semiconductor device.

2. The semiconductor device according to claim 1, wherein
a tape pattern is used to connect the electrode pads, the tape pattern being provided with a slit from the electrode pads near to the solder ball terminal so as to separate the electrode pads.

3. The semiconductor device according to claim 1, wherein
a lead frame is used to connect the electrode pads, the lead frame being provided with a slit from the electrode pads near to the solder ball terminal so as to separate the electrode pads.

4. A semiconductor device comprising:
a wiring substrate;
a semiconductor chip mounted on one side of the wiring substrate and on which a plurality of electrode pads having the same potential are arranged;
a solder ball terminal arranged on the other side opposing the one side of the wiring substrate;
plane pattern wiring for electrically connecting the plurality of electrode pads and the solder ball terminal; and
a slit extending from a connection part with the plurality of electrode pads in the plane pattern wiring toward the solder ball terminal.

5. The semiconductor device according to claim 4, wherein
the slit is configured to extend from the connection part having the plurality of electrode pads to a location near the solder ball terminal.

6. The semiconductor device according to claim 4, wherein
the slit is configured to extend from the connection part having the plurality of electrode pads to near a part where the wiring width of the plane pattern wiring is not more than 90 μm.

7. The semiconductor device according to claim 4, wherein
the plurality of electrode pads are electrode pads for ground or electrode pads for power.
